(19) United States
(12) Patent Application Publication
(10) Pub. No.: US 2024/0106203 A1
(43) Pub. Date: Mar. 28, 2024

(54) Laser Emitters with Integrated Thermal Sensors

(71) Applicant: Apple Inc., Cupertino, CA (US)

(72) Inventors: Chin Han Lin, Cupertino, CA (US); Yazan Z. Alnahhas, Stanford, CA (US); Fei Tan, Sunnyvale, CA (US)

(21) Appl. No.: 18/078,819

(22) Filed: Dec. 9, 2022

Related U.S. Application Data
(60) Provisional application No. 63/409,185, filed on Sep. 22, 2022.

(51) Int. Cl. H01S 5/42; H01S 5/024; H01S 5/125; H01S 5/183

(52) U.S. Cl. CPC H01S 5/423; H01S 5/024; H01S 5/125; H01S 5/183

(57) ABSTRACT

Embodiments of the disclosure relate to an optoelectronic device having an epitaxial stack, an array of laser emitters, and a thermal sensor. The epitaxial stack includes a set of epitaxial layers. The array of laser emitters is formed in the set of epitaxial layers. The thermal sensor is coupled to the epitaxial stack at a location adjacent to a laser emitter of the array of laser emitters. The optoelectronic device further includes a controller configured to receive an output of the thermal sensor and determine a temperature at a junction between an active region and an inactive region in the laser emitter by in-situ measurements.

### CROSS-REFERENCE TO RELATED APPLICATION

This application is a nonprovisional and claims the benefit under 35 U.S.C. 119(e) of U.S. Provisional Patent Application No. 63/409,185, filed Sep. 22, 2022, the contents of which are incorporated by reference as if fully disclosed herein.

### FIELD

The described embodiments relate generally to optoelectronic devices. More particularly, the present embodiments relate to optoelectronic devices having laser emitters with integrated thermal sensors.

### BACKGROUND

Cell phones, digital cameras, tablet computers, laptop computers, and other electronic devices may include optoelectronic devices. Some optoelectronic devices may include laser emitters. For example, one or more laser emitters may be used in conjunction with an imaging system or display panel, for application such as range finding or ambient light level detection.

### SUMMARY

The term embodiment and like terms, e.g., implementation, configuration, aspect, example, and option, are intended to refer broadly to all of the subject matter of this disclosure and the claims below. Statements containing these terms should be understood not to limit the subject matter described herein or to limit the meaning or scope of the claims below. Embodiments of the present disclosure covered herein are defined by the claims below, not this summary. This summary is a high-level overview of various aspects of the disclosure and introduces some of the concepts that are further described in the Detailed Description section below. This summary is not intended to identify key or essential features of the claimed subject matter. This summary is also not intended to be used in isolation to determine the scope of the claimed subject matter. The subject matter should be understood by reference to appropriate portions of the entire specification of this disclosure, any or all drawings, and each claim.

Embodiments of this disclosure are directed to an optoelectronic device having an epitaxial stack, an array of laser emitters, and a thermal sensor. The epitaxial stack includes a set of epitaxial layers. The array of laser emitters is formed in the set of epitaxial layers. The thermal sensor is coupled to the epitaxial stack at a location adjacent to a laser emitter of the array of laser emitters.

Embodiments of this disclosure are further directed to an optoelectronic device having an epitaxial stack, an array of laser emitters, a first thermal sensor, a second thermal sensor, and a controller. The epitaxial stack includes a set of epitaxial layers. The array of laser emitters is formed in the set of epitaxial layers. The array of laser emitters has a peripheral region including a first set of laser emitters and a central region including a second set of laser emitters. The first thermal sensor is coupled to the epitaxial stack at a first location adjacent to the first set of laser emitters. The second thermal sensor is coupled to the epitaxial stack at a second location adjacent to the second set of laser emitters. The controller is configured to receive a first output of the first thermal sensor and a second output of the second thermal sensor and determine a junction temperature at a junction between an active region and an inactive region in at least one of the laser emitters in each of the first set and the second set.

Embodiments of this disclosure are also directed to a method of measuring junction temperature at a junction between an active region and an inactive region of a laser emitter in an optoelectronic device. The method includes forming a thermal sensor adjacent to the junction during fabrication of the laser emitter wherein the thermal sensor is coupled to an epitaxial stack of the optoelectronic device. The method further includes calibrating a thermal resistance of the laser emitter. The method proceeds to switching on the laser emitter. The method subsequently includes taking an in-situ measurement of a biased junction temperature of the laser emitter using the thermal sensor. Finally, the method includes determining the junction temperature by comparing the measured biased junction temperature against the calibrated thermal resistance of the laser emitter.

The above summary is not intended to represent each embodiment or every aspect of the present disclosure. Rather, the foregoing summary merely provides an example of some of the novel aspects and features set forth herein. The above features and advantages, and other features and advantages of the present disclosure, will be readily apparent from the following detailed description of representative embodiments and modes for carrying out the present invention, when taken in connection with the accompanying drawings and the appended claims. Additional aspects of the disclosure will be apparent to those of ordinary skill in the art in view of the detailed description of various embodiments, which is made with reference to the drawings, a brief description of which is provided below.

### BRIEF DESCRIPTION OF THE DRAWINGS

The disclosure will be readily understood by the following detailed description in conjunction with the accompanying drawings, wherein like reference numerals designate like structural elements, and in which:

FIGS. 1A-1B show an isometric front view and an isometric rear view, respectively, of an example electronic device having an optoelectronic device, according to certain aspects of the present disclosure;

FIG. 2 shows a schematic representation of an optoelectronic device under operation, according to certain aspects of the present disclosure;

FIG. 3 shows a cross-sectional side view of a laser emitter in the optoelectronic device of FIG. 2, according to certain aspects of the present disclosure;

FIGS. 4A-4B show a cross-sectional side view and a cross-sectional top view, respectively, of a laser emitter with an integrated thermal sensor positioned in a trench area of an epitaxial stack in an optoelectronic device, according to certain aspects of the present disclosure;

FIGS. 5A-5B show a cross-sectional side view and a cross-sectional top view, respectively, of a laser emitter with an integrated thermal sensor mounted on a top surface of an epitaxial stack in an optoelectronic device, according to certain aspects of the present disclosure; and

FIG. 6 shows a block diagram of a method of measuring junction temperature of a laser emitter in the optoelectronic device of FIG. 2, according to certain aspects of the present disclosure.

The use of cross-hatching or shading in the accompanying figures is generally provided to clarify the boundaries between adjacent elements and also to facilitate legibility of the figures. Accordingly, neither the presence nor the absence of cross-hatching or shading conveys or indicates any preference or requirement for particular materials, material properties, element proportions, element dimensions, commonalities of similarly illustrated elements, or any other characteristic, attribute, or property for any element illustrated in the accompanying figures.

The present disclosure is susceptible to various modifications and alternative forms, and some representative embodiments have been shown by way of example in the drawings and will be described in detail herein. It should be understood, however, that the invention is not intended to be limited to the particular forms disclosed. Rather, the disclosure is to cover all modifications, equivalents, and alternatives falling within the spirit and scope of the invention as defined by the appended claims.

Additionally, it should be understood that the proportions and dimensions (either relative or absolute) of the various features and elements (and collections and groupings thereof) and the boundaries, separations, and positional relationships presented therebetween, are provided in the accompanying figures merely to facilitate an understanding of the various embodiments described herein and, accordingly, may not necessarily be presented or illustrated to scale, and are not intended to indicate any preference or requirement for an illustrated embodiment to the exclusion of embodiments described with reference thereto.

### DETAILED DESCRIPTION

Various embodiments are described with reference to the attached figures, where like reference numerals are used throughout the figures to designate similar or equivalent elements. The figures are not necessarily drawn to scale and are provided merely to illustrate aspects and features of the present disclosure. Numerous specific details, relationships, and methods are set forth to provide a full understanding of certain aspects and features of the present disclosure, although one having ordinary skill in the relevant art will recognize that these aspects and features can be practiced without one or more of the specific details, with other relationships, or with other methods. In some instances, well-known structures or operations are not shown in detail for illustrative purposes. The various embodiments disclosed herein are not necessarily limited by the illustrated ordering of acts or events, as some acts may occur in different orders and/or concurrently with other acts or events. Furthermore, not all illustrated acts or events are necessarily required to implement certain aspects and features of the present disclosure.

For purposes of the present detailed description, unless specifically disclaimed, and where appropriate, the singular includes the plural and vice versa. The word “including” means “including without limitation.” Moreover, words of approximation, such as “about,” “almost,” “substantially,” “approximately,” and the like, can be used herein to mean “at,” “near,” “nearly at,” “within 3-5% of,” “within acceptable manufacturing tolerances of,” or any logical combination thereof. Similarly, terms “vertical” or “horizontal” are intended to additionally include “within 3-5% of” a vertical or horizontal orientation, respectively.

Additionally, directional terminology, such as “top”, “bottom”, “upper”, “lower”, “front”, “back”, “over”, “under”, “above”, “below”, “left”, “right”, etc. is used with reference to the orientation of some of the components in some of the figures described below. Because components in various embodiments can be positioned in a number of different orientations, directional terminology is used for purposes of illustration only and is in no way limiting. The directional terminology is intended to be construed broadly, and therefore should not be interpreted to preclude components being oriented in different ways. These words are intended to relate to the equivalent direction as depicted in a reference illustration; as understood contextually from the object(s) or element(s) being referenced, such as from a commonly used position for the object(s) or element(s); or as otherwise described herein. Further, it is noted that the term “signal” means a waveform (e.g., electrical, optical, magnetic, mechanical or electromagnetic) capable of traveling through a medium such as DC, AC, sinusoidal-wave, triangular-wave, square-wave, vibration, and the like.

Also, as used herein, the phrase “at least one of” preceding a series of items, with the term “and” or “or” to separate any of the items, modifies the list as a whole, rather than each member of the list. The phrase “at least one of” does not require selection of at least one of each item listed; rather, the phrase allows a meaning that includes at a minimum one of any of the items, and/or at a minimum one of any combination of the items, and/or at a minimum one of each of the items. By way of example, the phrases “at least one of A, B, and C” or “at least one of A, B, or C” each refer to only A, only B, or only C; any combination of A, B, and C; and/or one or more of each of A, B, and C. Similarly, it may be appreciated that an order of elements presented for a conjunctive or disjunctive list provided herein should not be construed as limiting the disclosure to only that order provided.

A number of parameters need to be monitored in real-time during operation of an optoelectronic device. One of the most important parameters is temperature of a junction between an active region and an inactive region (alternatively, ‘junction temperature’) of a laser emitter in the optoelectronic device. The junction temperature impacts optical power, device reliability, as well as energy efficiency, of the optoelectronic device. Conventional methods of monitoring the junction temperature can be time-consuming or inaccurate. It is thus desirable to have laser emitters with integrated thermal sensors that can quickly and accurately monitor junction temperature, in order to ensure reliable and efficient operation of the optoelectronic device.

Embodiments of the disclosure are directed to optoelectronic devices having laser emitters with integrated thermal sensors. The optoelectronic device includes an epitaxial stack formed by growth of semiconductor layers over a semiconductor substrate. One or more laser emitters are fabricated into the epitaxial stack and configured to emit laser light. The thermal sensors are coupled to the epitaxial stack, and thus integrally formed with the laser emitters in the epitaxial stack during the fabrication process. The thermal sensor may be co-planar with layers in an active region in the laser emitter.

Generally, the thermal sensor may be coupled to the epitaxial stack at any location adjacent to the laser emitter. For purposes of this description, “adjacent” means directly next to or offset from, in a horizontal, vertical, or diagonal direction. In some embodiments, the thermal sensor may be mounted in a trench area of an epitaxial stack in an optoelectronic device, on a top surface of the epitaxial stack, on a bottom surface of the epitaxial stack, or on a distributed Bragg reflector formed in the epitaxial stack around the laser emitter. In other embodiments, the optoelectronic device may have a p-n diode structure having a cathode section disposed on a bottom surface of the epitaxial stack and an anode section disposed adjacent to the top surface of the epitaxial stack. In such embodiments, the thermal sensor may be mounted between a layer of the epitaxial stack and the anode section.

The thermal sensors are configured to take in-situ measurements of a junction temperature at a junction between an active region and an inactive region of the laser emitter. This enables quick and reliable monitoring of the junction temperature which indicates how reliably and efficiently the optoelectronic device operates.

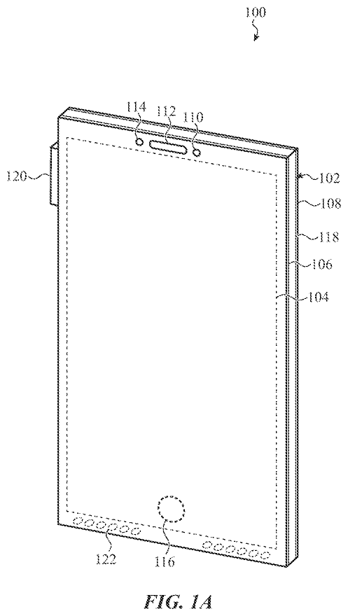

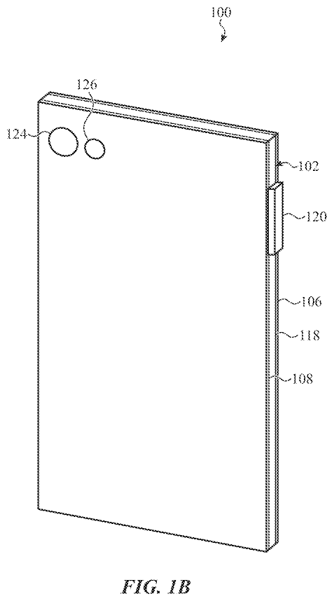

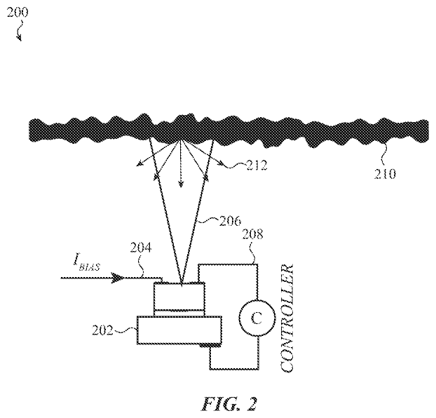

FIGS. 1A-1B show a perspective front view and a perspective rear view, respectively, of an example electronic device 100 having an optoelectronic device 200 (shown in FIG. 2). The dimensions and form factor of the electronic device 100, including the ratio of the length of its long sides to the length of its short sides, suggest that the electronic device 100 is a mobile phone (e.g., a smartphone). However, the device's dimensions and form factor are arbitrarily chosen, and the electronic device 100 could alternatively be any portable electronic device including, for example a mobile phone, tablet computer, portable computer, portable music player, wearable device (e.g., an electronic watch, health monitoring device, or fitness tracking device), augmented reality (AR) device, virtual reality (VR) device, mixed reality (MR) device, gaming device, portable terminal, digital single-lens reflex (DSLR) camera, video camera, vehicle navigation system, robot navigation system, or other portable or mobile device. The electronic device 100 could also be a device that is semi-permanently located (or installed) at a single location.

The electronic device 100 may include a housing 102 that at least partially surrounds a display 104. The housing 102 may include or support a front cover 106 that defines a front surface of the electronic device 100, and/or a back cover 108 that defines a back surface of the electronic device 100 (with the back surface opposite the front surface). More generically, the electronic device 100 may include one or more “covers.” The housing 102 may have a multi-segment sidewall 118 including a set of antennas, which may form structural components of the sidewall 118. The front cover 106 may be mounted to the sidewall 118 to cover an opening defined by the sidewall 118 (i.e., an opening into an interior volume, in which various electronic components of the electronic device 100, including the display 104, may be positioned). The front cover 106 may be mounted to the sidewall 118 using fasteners, adhesives, seals, gaskets, or other components.

The front cover 106 may be positioned over the display 104, and may provide a window through which the display 104 may be viewed. In some embodiments, the display 104 may be attached to (or abut) the housing 102 and/or the front cover 106. The display 104 may include one or more light-emitting elements, and in some cases may be a light-emitting diode (LED) display, an organic LED (OLED) display, a liquid crystal display (LCD), an electroluminescent (EL) display, a thin film transistor (TFT) display, or another type of display. In some embodiments, the display 104 may include, or be associated with, one or more touch and/or force sensors that are configured to detect a touch and/or a force applied to a surface of the front cover 106. As described below, the display 104 may be used in conjunction with an optoelectronic device having an array of laser emitters. The laser emitter may be a vertical-cavity surface-emitting laser (VCSEL), a vertical external-cavity surface-emitting laser (VECSEL), a horizontal cavity surface-emitting laser (HCSEL), a quantum-dot laser (QDL), a quantum cascade laser (QCL), or an edge-emitting laser (EEL).

As shown primarily in FIG. 1A, the electronic device 100 may include one or more front-facing cameras 110, speakers 112, microphones, or other components 114 (e.g., audio, imaging, and/or sensing components) that are configured to transmit or receive signals to/from the electronic device 100. In some cases, a front-facing camera 110, alone or in combination with other sensors, may be configured to operate as a bio-authentication or facial recognition sensor. In some embodiments, the facial recognition sensor may include an optoelectronic device. The electronic device 100 may also include various input devices, including a mechanical or virtual button 116, which may be accessible from the front surface (or display surface) of the electronic device 100. In some embodiments, a virtual button 116 may be displayed on the display 104 and, in some cases, a fingerprint sensor may be positioned under the button 116 and configured to image a fingerprint through the display 104. In some embodiments, the fingerprint sensor or another form of imaging device may span a greater portion, or all, of the display area.

The electronic device 100 may also include buttons or other input devices positioned along the sidewall 118 and/or on a back surface of the electronic device 100. For example, a volume button or multipurpose button 120 may be positioned along the sidewall 118, and in some cases may extend through an aperture in the sidewall 118. In other embodiments, the button 120 may take the form of a designated and possibly raised portion of the sidewall 118, but the button 120 may not extend through an aperture in the sidewall 118. The sidewall 118 may include one or more ports 122 that allow air, but not liquids, to flow into and out of the electronic device 100. In some embodiments, one or more sensors may be positioned in or near the port(s) 122. For example, an ambient pressure sensor, ambient temperature sensor, internal/external differential pressure sensor, gas sensor, particulate matter concentration sensor, or air quality sensor may be positioned in or near a port 122.

In some embodiments, the back surface of the electronic device 100 may include a rear-facing camera 124 that includes one or more image sensors (shown in FIG. 1B). In some cases, the electronic device 100 may have a second imaging sensor 126, which may be an autofocus camera, a telephoto camera, a second camera used in conjunction with the rear-facing camera 124—such as to provide depth or 3D imaging—or another optical sensor. The electronic device 100 may also have a flash or light source that may be positioned on the back of the electronic device 100 (e.g., near the rear-facing camera 124). In some cases, the back surface of the electronic device 100 may include multiple rear-facing cameras. One or both of the rear-facing camera 124 and the second imaging sensor 126 may include one or more optoelectronic devices having an array of laser emitters, similar to those described above.

FIG. 2 shows a schematic representation of the optoelectronic device 200 under operation. The optoelectronic device 200 makes use of a VCSEL diode 202 configured to emit laser light 206, which laser light may be directed toward an object 210. The VCSEL diode 202 may emit the laser light 206 under a forward voltage bias (or just “forward bias”) of its diode structure. During such forward bias, a bias current I_{BIAS} 204, flows through the VCSEL diode 202. Charge carriers crossing the p-n junction of the VCSEL diode 202 induce emission of laser light from the VCSEL diode 202. There may be reflections 212 of the emitted laser light 206, which may travel in multiple directions from the object 210.

The VCSEL diode 202 may be electrically connected to a controller 208. The controller 208 may be configured to control emission of the laser light from the VCSEL diode 202, as well as monitor junction temperature between an active region and an inactive region in the VCSEL diode 202 by receiving outputs of biased junction temperature from one or more thermal sensors integrally formed with the VCSEL diode 202, as discussed in greater detail below. In some embodiments, the controller 208 may be further configured to calibrate a thermal resistance of the VCSEL diode 202 using such thermal sensors.

The controller 208 may communicate, either directly or indirectly, with some or all of the other components of the optoelectronic device 200 and/or the electronic device 100. The controller 208 may be implemented as any electronic device or circuit capable of processing, receiving, or transmitting data or instructions, whether such data or instructions is in the form of software or firmware or otherwise encoded. For example, the controller 208 may include a microprocessor, a central processing unit (CPU), an application-specific integrated circuit (ASIC), a digital signal processor (DSP), a controller, or a combination of such devices. As described herein, the term “controller” is meant to encompass a single processor or processing unit, multiple processors, multiple processing units, or other suitably configured computing element or elements. In some cases, the controller 208 may provide part or all of the processing system or processor described herein. The controller 208 may be communicatively coupled to a memory for storing electronic and sensor data, and the memory may be a random access memory, read-only memory, Flash memory, removable memory, other types of storage elements, or combinations of such memory types.

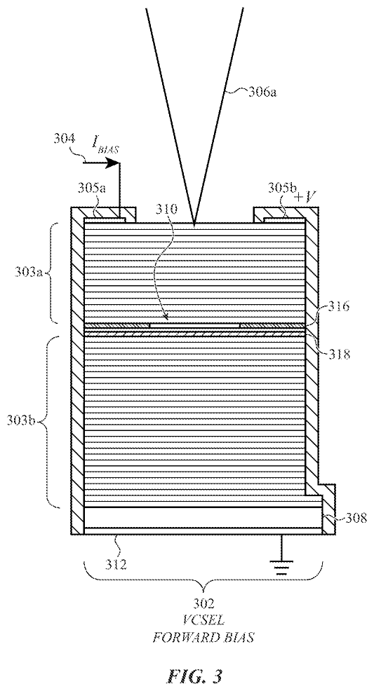

FIG. 3 shows a cross-sectional side view of an optoelectronic device 300 that is substantially similar to the optoelectronic device 200 (shown in FIG. 2). As shown, the optoelectronic device 300 includes a VCSEL diode 302 (similar to the VCSEL diode 202 in FIG. 2) under forward bias and emitting a laser light 306a. Under the forward bias, a bias current 304, I_{BIAS}, flows into the VCSEL diode 302, with some or all of it returning to a ground layer or contact 312.

The VCSEL diode 302 may include an emission side (or “top side”) distributed Bragg reflector 303a that functions as a first (or “emission side”) mirror of a laser structure. The top side distributed Bragg reflector 303a may include a set of pairs of alternating materials having different refractive indices. Each such pair of alternating materials will be termed herein a Bragg pair. One or more of the materials in the top side distributed Bragg reflector 303a are doped to be p-type and so form a part of the anode section of a p-n diode junction. An exemplary pair of materials that may be used to form the top side distributed Bragg reflector 303a are aluminum gallium arsenide (AlGaAs) and gallium arsenide (GaAs).

The VCSEL diode 302 may also include a base side distributed Bragg reflector 303b that functions as a second (or “base side”) mirror of a laser. The base side distributed Bragg reflector 303b may also include a set of Bragg pairs of alternating materials having different refractive indices. One or more of the materials in the base side distributed Bragg reflector 303b are doped to be n-type and so form a part of the cathode section of a p-n diode structure. An exemplary pair of materials that may be used to form the base side distributed Bragg reflector 303b are aluminum arsenide and gallium arsenide.

The VCSEL diode 302 may include an active region 318 that functions in part as the lasing cavity. In laser emitters, such as VCSEL diode 302, the active region 318 may include one or more quantum wells. The active region 318 of VCSEL diode 302 may be adjacent to an oxide layer 316, having an aperture through which the emitted laser light 306a escapes.

The VCSEL diode 302 may be formed by epitaxial growth of the layers for each of the top side distributed Bragg reflector 303a, and base side distributed Bragg reflector 303b, the active region 318 and the oxide layer 316, and possibly other layers. These various layers may be formed by epitaxial growth on a substrate layer 308, with the ground layer or contact 312 formed afterwards. Electrical supply contacts 305a, 305b may be formed on the outermost (i.e., emission side) layer of the VCSEL diode 302. While shown as separated in FIG. 3A, the electrical supply contacts 305a, 305b may be connected, such as to form, for example, by a ring or horseshoe connection on the top side of the VCSEL diode 302.

The VCSEL diode 302 may alternatively be formed by epitaxial growth from a substrate starting with the layers for the top side distributed Bragg reflector 303a. The substrate may then be separated from a substrate, such as by etching or cleaving, and a flip chip process used to attach the VCSEL diode 302 to another substrate or circuit, so that the top side distributed Bragg reflector 303a is configured to emit the laser light 306a.

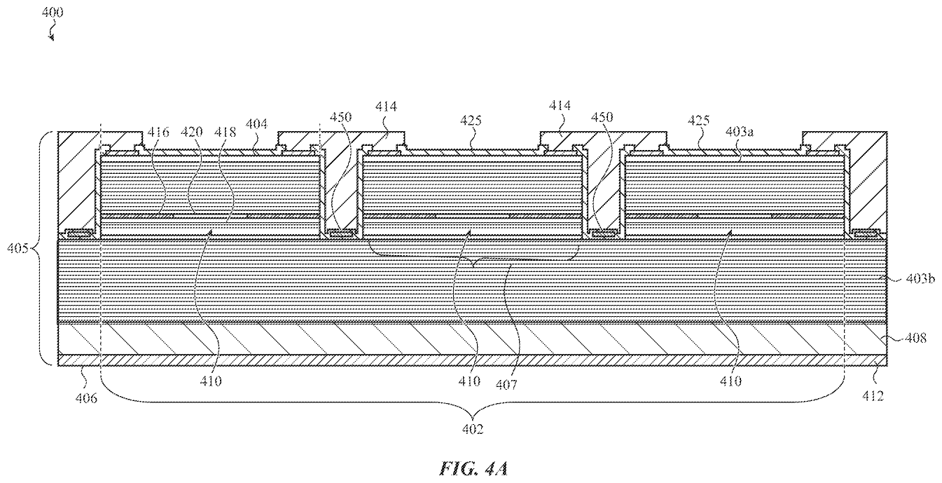

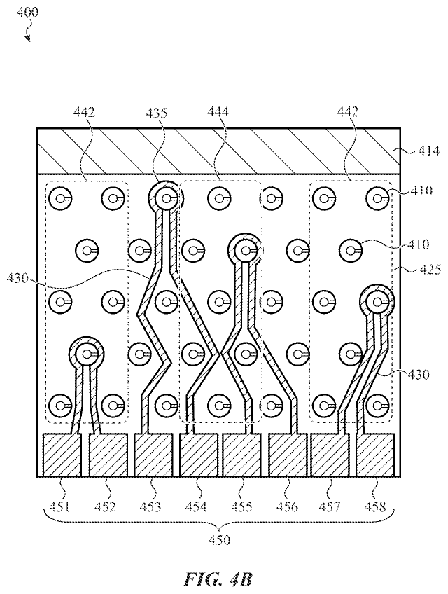

FIGS. 4A-4B show a cross-sectional side view and a cross-sectional top view, respectively, of an example optoelectronic device 400, where a thermal sensor 450 is integrally formed in a trench area 407 of an epitaxial stack 405 forming the optoelectronic device 400. The optoelectronic device 400 has an array 402 of laser emitting diodes 410 formed therein. The optoelectronic device 400 includes an epitaxial stack 405 of semiconductor epitaxial layers that are grown epitaxially over a substrate layer 408 formed from a semiconductor material such as, but not limited to, gallium arsenide (GaAs). The epitaxial stack 405 has a top surface 404 and a bottom surface 406 that is adjacent to the substrate layer 408. The laser emitting diode 410 is epitaxially grown over the substrate layer 408 between a top side distributed Bragg reflector 403a and a base side distributed Bragg reflector 403b. The top side distributed Bragg reflector 403a and the base side distributed Bragg reflector 403b are substantially similar to the top side distributed Bragg reflector 303a and the base side distributed Bragg reflector 303b, discussed above with respect to FIG. 3.

The optoelectronic device 400 has a p-n diode structure with a cathode section 412 and an anode section 414. The cathode section 412 is disposed on the bottom surface 406 of the epitaxial stack 405. The anode section 414 is disposed adjacent to the top surface 404 of the epitaxial stack 405. A dielectric layer 425 is disposed over the top surface 404 and around the anode section 414 in order to isolate the anode section 414 from a bias current flowing into the laser emitting diode 410.

In the embodiment shown in FIG. 4A, the thermal sensor 450 is mounted between a layer of the epitaxial stack 405 and the anode section 414. However, in different embodiments, the thermal sensor 450 may be mounted in the trench area 407, on the top surface 404 of the epitaxial stack 405, on the bottom surface 406 of the epitaxial stack 405, on the top side distributed Bragg reflector 403a or the base side distributed Bragg reflector 403b. Generally, the thermal sensor 450 may be coupled to the epitaxial stack 405 at any location adjacent to the laser emitting diode 410. In some embodiments, the thermal sensor 450 may be co-planar with one of the epitaxial layers in an active region 418 of each laser emitting diode 410. The thermal sensor 450 may be a resistance temperature detector (RTD) or a negative temperature coefficient thermistor. As an example, a metal like titanium can be used to form the RTD and deposited during fabrication of the laser emitting diode 410.

The laser emitting diode 410 includes the active region 418 and an inactive region 416. The active region 418 includes one or more quantum wells and functions as a lasing cavity for the laser emitting diode 410. The inactive region 416 includes an oxide layer having an aperture through which a laser light is emitted. During operation of the optoelectronic device 400, the junction 420 between the active region 418 and the inactive region 416 generates heat, and therefore must be critically monitored. The thermal sensor 450 is configured to take in-situ measurements of a biased junction temperature of the laser emitting diode 410. The measured biased junction temperature is then compared against a calibrated thermal resistance of the laser emitting diode 410.

As shown in the cross-sectional top view of FIG. 4B, a plurality of laser emitting diodes 410 is disposed over the dielectric layer 425 on the topmost epitaxial layer of the epitaxial stack 405. The anode section 414 is located at one end of the optoelectronic device 400. The plurality of laser emitting diodes 410 are distributed along a peripheral region 442 and a central region 444 on the optoelectronic device 400. The peripheral region 442 and the central region 444 may each have a number of laser emitting diodes 410, though the exact number in each region may vary.

FIG. 4B further shows the thermal sensor 450 having a plurality of electrodes 451, 452, 453, 454, 455, 456, 457, and 458 that are mounted on the opposite end to the anode section 414. Each of the electrodes 451, 452, 453, 454, 455, 456, 457, and 458 includes a thermally conductive trace 430 separated from the epitaxial stack 405 by the dielectric layer 425. The electrodes 451, 452, 453, 454, 455, 456, 457, and 458 are capable of detecting changes in resistance of the thermally conductive trace 430 (e.g., by measuring a change in voltage when a current is flown through the thermally conductive trace 430). The thermal sensor 450 further includes a temperature detection portion 435 that loops around the laser emitting diodes 410. The temperature detection portion 435 of each thermally conductive trace 430 may be substantially more thermally sensitive than the rest of the thermally conductive trace 430, so that the biased junction temperature is measured at a discrete location directly adjacent to the laser emitting diode 410.

The electrodes 451, 452 are coupled to the epitaxial stack 405 adjacent to the peripheral region 442 on one side, while the electrodes 457, 458 are coupled to the epitaxial stack 405 adjacent to the peripheral region 442 on the opposite side. The electrodes 454, 455 are coupled to the epitaxial stack 405 adjacent to the central region 444 of the optoelectronic device 400. This distribution of the electrodes 451, 452, 453, 454, 455, 456, 457, and 458 enables accurate measurement of junction temperatures at both the peripheral regions 442 and the central region 444, which tend to vary from each other. Further, the distribution of the electrodes 451, 452, 453, 454, 455, 456, 457, and 458 enables determination (e.g., by the controller 208 in FIG. 2) of average junction temperatures in both the peripheral regions 442 and the central region 444. For example, outputs of the electrodes 451, 452 may help determine an average junction temperature in the peripheral region 442. Similarly, the outputs of the electrodes 454, 455 may help determine an average junction temperature in the central region 444.

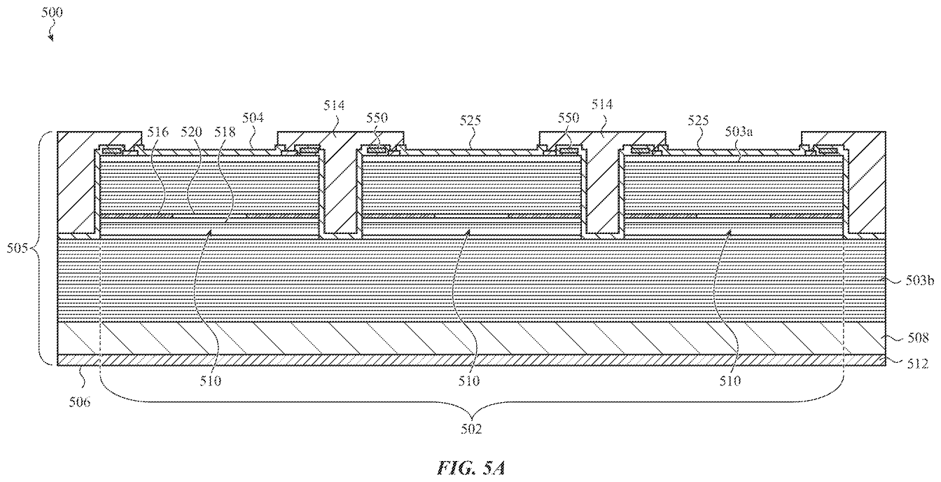

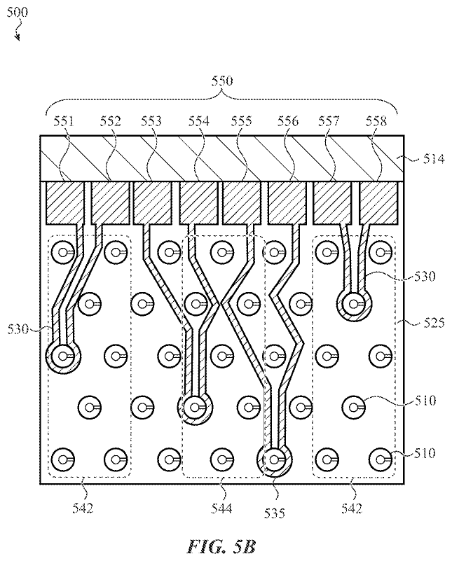

FIGS. 5A-5B show a cross-sectional side view and a cross-sectional top view, respectively, of an example optoelectronic device 500, where a thermal sensor 550 is integrally mounted on a top surface 504 of an epitaxial stack 505 forming the optoelectronic device 500. The optoelectronic device 500 has an array 502 of laser emitting diodes 510 formed therein. The optoelectronic device 500 includes the epitaxial stack 505 of semiconductor epitaxial layers that are grown epitaxially over a substrate layer 508 formed from a semiconductor material such as, but not limited to, gallium arsenide (GaAs). The epitaxial stack 505 has a top surface 504 and a bottom surface 506 that is adjacent to the substrate layer 508. The laser emitting diode 510 is epitaxially grown over the substrate layer 508 between a top side distributed Bragg reflector 503a and a base side distributed Bragg reflector 503b. The top side distributed Bragg reflector 503a and the base side distributed Bragg reflector 503b are substantially similar to the top side distributed Bragg reflector 303a and the base side distributed Bragg reflector 303b, discussed above with respect to FIG. 3.

The optoelectronic device 500 has a p-n diode structure with a cathode section 512 and an anode section 514. The cathode section 512 is disposed on the bottom surface 506 of the epitaxial stack 505. The anode section 514 is disposed adjacent to the top surface 504 of the epitaxial stack 505. A dielectric layer 525 is disposed over the top surface 504 and around the anode section 514 in order to isolate the anode section 514 from a bias current flowing into the laser emitting diode 510.

In the embodiment shown in FIG. 5A, the thermal sensor 550 is mounted on flanges of the anode section 514 adjacent to the top surface 504 of the epitaxial stack 505. However, in different embodiments, the thermal sensor 550 may be mounted adjacent to the bottom surface 506 of the epitaxial stack 505, mounted on the top side distributed Bragg reflector 503a or the base side distributed Bragg reflector 503b. Generally, the thermal sensor 550 may be coupled to the epitaxial stack 505 at any location adjacent to the laser emitting diode 510. In some embodiments, the thermal sensor 550 may be co-planar with one of the epitaxial layers in an active region 518 of each laser emitting diode 510. The thermal sensor 550 may be a resistance temperature detector (RTD) or a negative temperature coefficient thermistor. As an example, a metal like titanium can be used to form the RTD and deposited during fabrication of the laser emitting diode 510.

The laser emitting diode 510 includes the active region 518 and an inactive region 516. The active region 518 includes one or more quantum wells and functions as a lasing cavity for the laser emitting diode 510. The inactive region 516 includes an oxide layer having an aperture through which a laser light escapes. During operation of the optoelectronic device 500, the junction 520 between the active region 518 and the inactive region 516 generates heat, and therefore must be critically monitored. The thermal sensor 550 is configured to take in-situ measurements of a biased junction temperature of the laser emitting diode 510. The measured biased junction temperature is then compared against a calibrated thermal resistance of the laser emitting diode 510.

As shown in the cross-sectional top view of FIG. 5B, a plurality of laser emitting diodes 510 is disposed over the dielectric layer 525 on the topmost epitaxial layer of the epitaxial stack 505. The anode section 514 is located at one end of the optoelectronic device 500. The plurality of laser emitting diodes 510 are distributed along a peripheral region 542 and a central region 544 on the optoelectronic device 500. The peripheral region 542 and the central region 544 may each have a number of laser emitting diodes 510, though the exact number in each region may vary.

FIG. 5B further shows the thermal sensor 550 having a plurality of electrodes 551, 552, 553, 554, 555, 556, 557, and 558 that are mounted on the same end of the optoelectronic device 500 as the anode section 514. Each of the electrodes 551, 552, 553, 554, 555, 556, 557, and 558 includes a thermally conductive trace 530 separated from the epitaxial stack 505 by the dielectric layer 525. The electrodes 551, 552, 553, 554, 555, 556, 557, and 558 are capable of detecting changes in resistance of the thermally conductive trace 530 (e.g., by measuring a change in voltage when a current is flown through the thermally conductive trace 530). The thermal sensor 550 further includes a temperature detection portion 535 that loops around the laser emitting diodes 510. The temperature detection portion 535 of each thermally conductive trace 530 may be substantially more thermally sensitive than the rest of the thermally conductive trace 530, so that the biased junction temperature is measured at a discrete location directly adjacent to the laser emitting diode 510.

The electrodes 551, 552 are coupled to the epitaxial stack 505 adjacent to the peripheral region 542 on one side, while the electrodes 557, 558 are coupled to the epitaxial stack 505 adjacent to the peripheral region 542 on the opposite side. The electrodes 554, 555 are coupled to the epitaxial stack 505 adjacent to the central region 544 of the optoelectronic device 500. This distribution of the electrodes 551, 552, 553, 554, 555, 556, 557, and 558 enables accurate measurement of junction temperatures at both the peripheral regions 542 and the central region 544, which tend to vary from each other. Further, the distribution of the electrodes 551, 552, 553, 554, 555, 556, 557, and 558 enables determination (e.g., by the controller 208 in FIG. 2) of average junction temperatures in both the peripheral regions 542 and the central region 544. For example, outputs of the electrodes 551, 552 may help determine an average junction temperature in the peripheral region 542. Similarly, the outputs of the electrodes 554, 555 may help determine an average junction temperature in the central region 544.

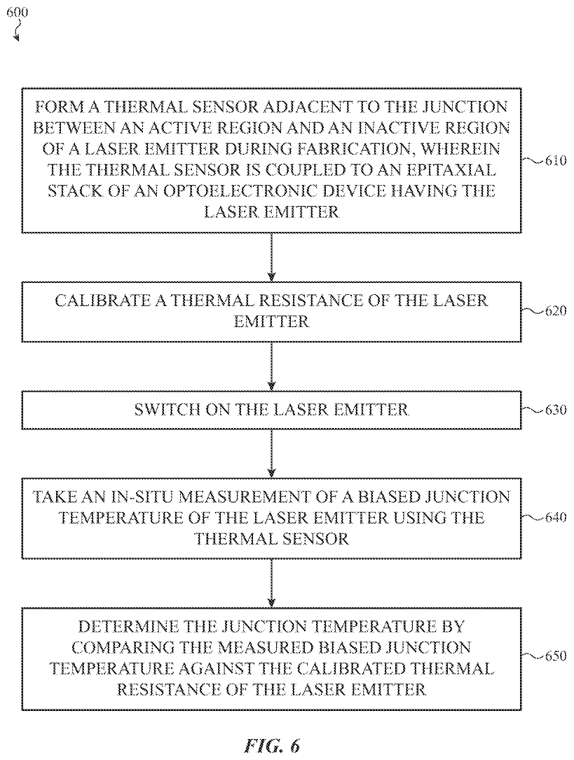

FIG. 6 shows a block diagram 600 of a method of measuring junction temperature of a laser emitter in the optoelectronic devices 300, 400, and 500 as shown in FIG. 3, FIGS. 4A-4B, and FIGS. 5A-5B respectively. In block 610, a thermal sensor is formed adjacent to a junction between an active region (e.g., active region 318 in FIG. 3) and an inactive region (e.g., oxide layer 316 in FIG. 3) during fabrication of a laser emitter in an optoelectronic device. The thermal sensor is coupled to an epitaxial stack formed by growth of semiconductor layers over a semiconductor substrate of the optoelectronic device. In some embodiments, such as those described above, the thermal sensor may be a resistance temperature detector, or a negative temperature coefficient thermistor. The thermal sensor may include one or more thermally conductive traces separated from at least one of the layers in the epitaxial stack by a dielectric layer thereon.

The thermal sensor may be co-planar with layers in the active region in the laser emitter. In some embodiments, the thermal sensor may be mounted in a trench area of the epitaxial stack, on a top surface of the epitaxial stack, on a bottom surface of the epitaxial stack, or on a distributed Bragg reflector formed in the epitaxial stack around the laser emitter. In other embodiments, the optoelectronic device may have a p-n diode structure having a cathode section disposed on a bottom surface of the epitaxial stack and an anode section disposed adjacent to a top surface of the epitaxial stack. In such embodiments, the thermal sensor may be mounted between a layer of the epitaxial stack and the anode section.

In block 620, a thermal resistance of the laser emitter is calibrated. In some embodiments, the calibration process may involve the thermal sensor integrally formed with the laser emitter. During the calibration process, the laser emitter is electrically unbiased initially. Then, a thermal resistance value of the laser emitter is measured at a plurality of temperatures using the thermal sensor. The measured thermal resistance values are then tabulated such that each thermal resistance value corresponds to each of the plurality of temperatures where the thermal resistance value is measured.

In block 630, the laser emitter is operated by turning on a switch. During this step, laser light is emitted from the active region, as described above. As a result, the junction area between the active region and the inactive region above it starts to generate heat. In block 640, an in-situ measurement of a biased junction temperature of the laser emitter is taken using the thermal sensor integrated with the laser emitter, while the laser emitter is in operation. A controller (e.g., the controller 208 in FIG. 2) receives outputs of the thermal sensors to determine the junction temperature between the active region and the inactive region of the laser emitter.

In block 650, the junction temperature between the active region and the inactive region of the laser emitter is determined by comparing the measured biased junction temperature against the calibrated thermal resistance of the laser emitter. In some embodiments, an average junction temperature may be determined by taking the average of junction temperatures measured by outputs of thermal sensors at two or more laser emitters. In some embodiments, the determined junction temperatures may pertain to thermal sensors integrated with laser emitters in a peripheral region as well as a central region of an array of laser emitters in the optoelectronic device.

Although the disclosed embodiments have been illustrated and described with respect to one or more implementations, equivalent alterations and modifications will occur or be known to others skilled in the art upon the reading and understanding of this specification and the annexed drawings. In addition, while a particular feature of the invention may have been disclosed with respect to only one of several implementations, such feature may be combined with one or more other features of the other implementations as may be desired and advantageous for any given or particular application.

While various embodiments of the present disclosure have been described above, it should be understood that they have been presented by way of example only, and not limitation. Numerous changes to the disclosed embodiments can be made in accordance with the disclosure herein, without departing from the spirit or scope of the disclosure. Thus, the breadth and scope of the present disclosure should not be limited by any of the above described embodiments. Rather, the scope of the disclosure should be defined in accordance with the following claims and their equivalents.

What is claimed is:

1. An optoelectronic device comprising:
an epitaxial stack comprising a set of epitaxial layers;
an array of laser emitters formed in the set of epitaxial layers; and
a thermal sensor coupled to the epitaxial stack at a location adjacent to a laser emitter of the array of laser emitters.

2. The optoelectronic device of claim 1, further comprising:
a p-n diode structure having a cathode section located at a bottom surface of the epitaxial stack and an anode section located adjacent to a top surface of the epitaxial stack, wherein the thermal sensor is mounted between a layer of the epitaxial stack and the anode section.

3. The optoelectronic device of claim 1, wherein the thermal sensor is mounted in a trench area of the epitaxial stack.

4. The optoelectronic device of claim 1, wherein the thermal sensor is mounted on a top surface of the epitaxial stack.

5. The optoelectronic device of claim 1, wherein the thermal sensor is mounted on a bottom surface of the epitaxial stack.

6. The optoelectronic device of claim 1, wherein the thermal sensor is mounted on a distributed Bragg reflector in the epitaxial stack.

7. The optoelectronic device of claim 1, wherein the thermal sensor is co-planar with an active layer of each laser emitter of the array of laser emitters.

8. The optoelectronic device of claim 1, wherein the thermal sensor comprises a resistance temperature detector or a negative temperature coefficient thermistor.

9. The optoelectronic device of claim 1, further comprising:
a dielectric layer on at least one epitaxial layer of the set of epitaxial layers;
wherein the thermal sensor includes a thermally conductive trace separated from the at least one epitaxial layer by the dielectric layer.

10. The optoelectronic device of claim 1, further comprising at least a second thermal sensor coupled to the epitaxial stack at a second location adjacent to a second laser emitter of the array of laser emitters.

11. The optoelectronic device of claim 1, wherein the laser emitter is a vertical cavity surface emitting laser (VCSEL) diode.

12. An optoelectronic device comprising:
an epitaxial stack comprising a set of epitaxial layers;
an array of laser emitters formed in the set of epitaxial layers, the array of laser emitters having a peripheral region including a first set of laser emitters and a central region including a second set of laser emitters,
a first thermal sensor coupled to the epitaxial stack at a first location adjacent to the first set of laser emitters;
a second thermal sensor coupled to the epitaxial stack at a second location adjacent to the second set of laser emitters; and
a controller configured to receive a first output of the first thermal sensor and a second output of the second thermal sensor and determine a junction temperature at a junction between an active region and an inactive region in at least one of the laser emitters in each of the first set and the second set.

13. The optoelectronic device of claim 12, wherein each of the first location and the second location is in a respective trench area of the epitaxial stack.

14. The optoelectronic device of claim 12, wherein each of the first location and the second location are on a top surface of the epitaxial stack.

15. The optoelectronic device of claim 12, wherein the controller is further configured to calibrate a thermal resistance of the at least one of the laser emitters in each of the first set and the second set using the first thermal sensor and the second thermal sensor respectively.

16. The optoelectronic device of claim 12, wherein:
the first set includes two or more laser emitters, each laser emitter integrated with a corresponding thermal sensor; and
the second set includes two or more laser emitters; and
the controller is further configured to receive outputs from each thermal sensor and determine an average junction temperature of the first set of laser emitters in the peripheral region.

17. The optoelectronic device of claim 12, wherein the first thermal sensor and the second thermal sensor are integrally formed with at least one of the laser emitters in each of the first set and the second set during a fabrication process thereof.

18. A method of measuring junction temperature at a junction between an active region and an inactive region of a laser emitter in an optoelectronic device, the method comprising:
forming a thermal sensor adjacent to the junction during fabrication of the laser emitter, the thermal sensor coupled to an epitaxial stack of the optoelectronic device;
calibrating a thermal resistance of the laser emitter;
switching on the laser emitter;
taking an in-situ measurement of a biased junction temperature of the laser emitter using the thermal sensor; and
determining the junction temperature by comparing the measured biased junction temperature against the calibrated thermal resistance of the laser emitter.

19. The method of claim 18, wherein calibrating the thermal resistance of the laser emitter comprises:
electrically unbiasing the laser emitter;
measuring a thermal resistance value of the laser emitter at a plurality of temperatures using the thermal sensor; and
determining a table of thermal resistance values corresponding to each of the plurality of temperatures.

20. The method of claim 18, wherein the thermal sensor comprises a resistance temperature detector or a negative temperature coefficient thermistor.
